(19) United States
(12) Patent Application Publication
(10) Pub. No.: US 2025/0301919 A1
(43) Pub. Date: Sep. 25, 2025

(54) METHOD OF MANUFACTURING A SUPERCONDUCTING INTEGRATED CIRCUIT DEVICE

(71) Applicant: Infineon Technologies AG, Neubiberg (DE)

(72) Inventors: Jochen BRAUMÜLLER, Holzkirchen (DE); Michael KIRSCH, Regensburg (DE); Wolfgang RABERG, Sauerlach (DE); Jash BANKER, Unterhaching (DE); Nicolas ARLT, München (DE)

(21) Appl. No.: 19/079,240

(22) Filed: Mar. 13, 2025

(30) Foreign Application Priority Data
Mar. 21, 2024 (DE) 102024202708.1

(51) Int. Cl. H10N 60/01; H10N 60/12; H10N 69/00

(52) U.S. Cl. CPC H10N 60/0912; H10N 60/12; H10N 69/00

(57) ABSTRACT

A method of manufacturing a superconducting integrated circuit device includes providing a Josephson Junction (JJ) structure on a first structured superconducting layer arranged on a substrate. Forming a cover layer over the first structured superconducting layer, including forming a first component from a sacrificial material in a first region of the cover layer, the first component surrounding the JJ structure with at least a portion of a top surface of the JJ structure, facing away from the substrate, being uncovered by the sacrificial material, and forming a second component from a first dielectric material in a second region of the cover layer. A via is formed in the cover layer over a portion of the first structured superconducting layer. A second structured superconducting layer is formed overlaying the top surface of the JJ structure and the via. The sacrificial material is removed.

### CROSS-REFERENCE TO RELATED APPLICATION

This application claims priority to Germany Patent Application No. 102024202708.1 filed on Mar. 21, 2024, the content of which is incorporated by reference herein in its entirety.

### TECHNICAL FIELD

This disclosure relates generally to the field of superconducting integrated circuits, and in particular to integration concepts for Josephson junctions on substrates.

### BACKGROUND

Electronic devices including a superconducting integrated circuit are used in the art in various technical fields. For example, quantum computing devices operating one or a plurality of superconducting quantum bits (qubits) rely on superconducting integrated circuits. Quantum computing based on these superconducting circuits constitute a leading platform on the quest to realize quantum hardware that is capable of performing useful computations that are beyond the reach of classical supercomputers. Circuits with up to several tens of superconducting qubits (and few hundreds in some instances) have been used to demonstrate proof-of-concept computations within the present noisy intermediate-scale quantum (NISQ) technology era, in which non-error-corrected, error-prone physical qubits are used to perform quantum simulations and quantum algorithms. First concept demonstrations towards quantum error correction—the holy grail in the field of quantum computations—have been achieved recently, however further emphasizing the yearn for physical qubits with higher coherence. One approach to realize circuits for such a quantum computer is to create qubits including superconducting Josephson junctions and capacitors. Superconducting integrated circuits including Josephson junctions are also used in single flux quantum (SFQ) devices and traveling-wave parametric amplifiers (TWPAs).

One central source of error in superconducting qubits is dielectric loss. It occurs when electric fields of the circuit penetrate a dielectric material that contains microscopic defects—so-called two-level systems (TLS). Their origin is not entirely understood but they are oftentimes visualized as an atom or a group of atoms that oscillate between two spatial configurations in the amorphous dielectric. The dipole moment of a TLS couples to the electric field of the quantum circuit, leading to a lifetime decrease of qubits. Since individual low-energy excitations are used to encode quantum states in qubits, such TLS interactions significantly impact the performance of physical qubits.

Electric fields in superconducting qubit circuits occur between disconnected conductors at different electric potentials, such as in configured or parasitic circuit capacitors. A typical location where parasitic capacitors exist is in the direct vicinity of tri-layer Josephson junctions, which are formed by two superconducting electrodes that are separated by a thin dielectric barrier (for example aluminum oxide). While the Josephson junction itself comprises an intrinsic capacitance due to its parallel-plate configuration, additional parasitic capacitance originates from the fringing fields surrounding the Josephson junction, penetrating regions that are oftentimes filled with lossy dielectrics that form a dielectric enclosure. Dielectric loss occurring in these regions deteriorates the performance of qubits built with such Josephson junctions.

### SUMMARY

According to an aspect of the disclosure, a method of manufacturing a superconducting integrated circuit device includes providing a Josephson Junction (JJ) structure arranged on a first structured superconducting layer, wherein the first structured superconducting layer is formed from a first superconducting material arranged on a substrate. A cover layer having a first component and a second component is formed over the first structured superconducting layer. Forming the cover layer includes forming the first component from a sacrificial material in a first region of the cover layer, the first component surrounding the JJ structure with at least a portion of a top surface of the JJ structure facing away from the substrate being uncovered by the sacrificial material, and forming the second component from a first dielectric material in a second region of the cover layer different from the first region. A via is formed in the cover layer over a portion of the first structured superconducting layer. A second structured superconducting layer of a second superconducting material is formed overlaying the top surface of the JJ structure and the via. The sacrificial material is removed. Thus, the JJ structure is not in contact with any dielectric material, hence alleviating dielectric losses.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated implementations can be combined unless they exclude each other and/or can be selectively omitted if not described to be necessarily required. Implementations are depicted in the drawings and are exemplarily detailed in the description which follows.

FIGS. 1, 2a, 3, 4, 5a, 6a, and 7a are schematic cross-sectional views illustrating stages of a method of manufacturing a superconducting integrated circuit device in accordance with a first implementation.

FIGS. 2b, 5b, 6b, and 7b are schematic top views further illustrating the stages of the method of manufacturing the superconducting integrated circuit device in accordance with the first implementation.

FIGS. 8 to 11 are schematic cross-sectional views illustrating stages of a method of manufacturing a superconducting integrated circuit device in accordance with a second implementation.

### DETAILED DESCRIPTION

The words “over” or “beneath” or similar words with regard to a part, element or material layer formed or located or disposed or arranged or placed “over” or “beneath” a surface may be used herein to mean that the part, element or material layer be located (e.g., placed, formed, arranged, disposed, etc.) “directly on” or “directly under”, e.g., in direct contact with, the implied surface. The word “over” or “beneath” or similar words used with regard to a part, element or material layer formed or located or disposed or arranged or placed “over” or “beneath” a surface may, however, either be used herein to mean that the part, element or material layer be located (e.g., placed, formed, arranged, deposited, etc.) “indirectly on” or “indirectly under” the implied surface, with one or more additional parts, elements or layers being arranged between the implied surface and the part, element or material layer.

The following description relates by way of example to methods of manufacturing a superconducting integrated circuit device containing a Josephson junction. Superconducting integrated circuits (or devices) using a Josephson junction are examples of superconducting quantum circuits (or devices), since the Josephson effect is based on a quantum mechanical tunneling process.

For example, the methods may be used to implement quantum computing devices. However, the disclosure is not limited to methods of manufacturing quantum computing devices. Rather, the disclosure basically covers all methods of manufacturing superconducting integrated circuitry containing a Josephson junction, e.g., a superconducting Josephson junction quantum circuit.

In some examples, the superconducting integrated circuit may, e.g., comprise or be a resonating circuit. A resonating circuit typically comprises (at least) a capacitor and an inductor. The resonating circuit can be a linear resonating circuit (e.g., harmonic oscillator) or a nonlinear resonating circuit (e.g., anharmonic oscillator). In quantum devices such resonating circuits are also referred to as quantum oscillators (QO).

A known technique which is, e.g., used in quantum computing is to use a Josephson junction to make a resonating circuit nonlinear (or, differently stated, the oscillator potential anharmonic). In quantum computing devices, quantum anharmonic oscillators are used to “form” qubits. Differently put, a nonlinear resonating circuit may “form” (or operate as) a qubit. Qubits created by one or more (nonlinear) Josephson junctions in a (thus nonlinear) resonating circuit are sometimes also referred to as “Josephson qubits” in the art.

Other examples of superconducting Josephson junction quantum circuits are Josephson parametric amplifiers or traveling wave parametric amplifiers (TWPAs). These devices offer high gain at a bandwidth of several GHz, high dynamic range, and (nearly) quantum-limited noise. For example, to build a large-scale multi-qubit quantum processor, qubit readout by multiplexing is desirable, which requires amplifiers with a large bandwidth, high dynamic range, and low added noise. Such a capability is provided by traveling-wave parametric amplifiers (TWPAs).

Other examples of electronic devices including a superconducting integrated circuit are single flux quantum (SFQ) devices. Such devices are devices in which voltage pulses produced by Josephson junctions in the superconducting electronic (quantum) circuit (instead of the voltage levels produced by transistors in semiconductor electronics) are used to encode, process, and transport (classical) digital information. A superconducting integrated circuit containing a plurality of SFQ devices allows the formation of (R)SFQ ((rapid) single flux quantum) logic.

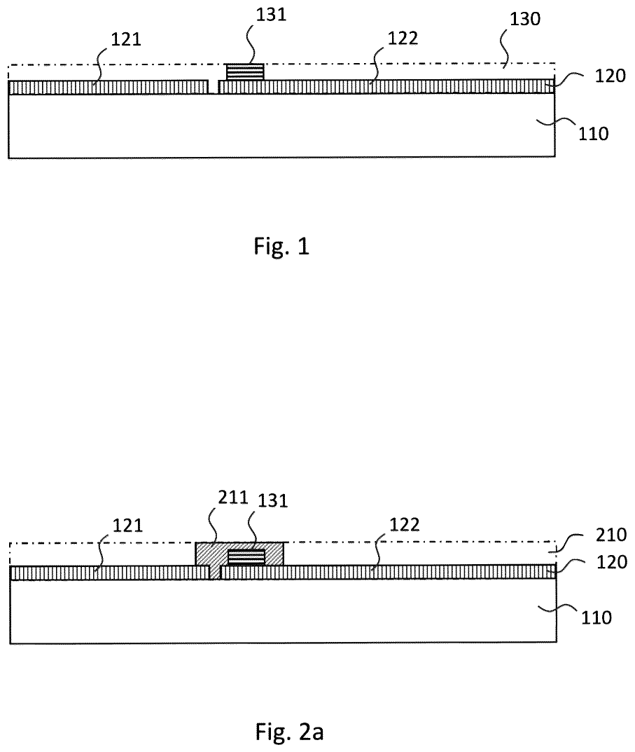

Referring to FIG. 1, a substrate 110 is provided. The substrate 110 may, e.g., comprise or be a sapphire substrate or a silicon substrate, in particular a high-resistive crystalline silicon substrate. The substrate 110 serves as a carrier for a superconducting integrated circuit to be built thereon. The substrate 110 may, e.g., be unstructured or unprocessed. In particular, no integrated circuits or integrated devices are formed in the substrate 110, for example.

A first structured superconducting layer 120 of a first superconducting material is formed over the substrate 110. The first structured superconducting layer 120 may be obtained by structuring an unstructured, continuous layer of the first superconducting material which may, e.g., be deposited on the entire substrate 110. For example, the unstructured, continuous layer of the first superconducting material may be deposited by using a CVD (chemical vapor deposition) or PVD (physical vapor deposition) process, in particular by sputtering. The first superconducting material is a material which can become superconducting at the operating temperature of the superconducting integrated circuit to be formed. Hence, the term “superconducting” refers to the state of conductivity of the material at operating temperature of the circuit. The superconducting material may, e.g., comprise or be of aluminum (Al), niobium (Nb), or tantalum (Ta).

The unstructured, continuous layer of the first superconducting material may then be structured to form the first structured superconducting layer 120. The first structured superconducting layer 120 includes a first superconducting structure 121 and a second superconducting structure 122 of the first superconducting material. The superconducting structures 121, 122 may, e.g., be electrically and/or structurally disconnected from each other.

For example, the first structured superconducting layer 120 may be obtained by a patterning process using, e.g., a photolithographic mask, a photoresist (not shown) and an etching process applied to the unstructured, continuous layer of the first superconducting material. Other structuring processes, which may be compatible with semiconductor manufacturing, may also be used.

A Josephson junction (JJ) layer stack 130 is formed over the first structured superconducting layer 120 (which, in this implementation, is already structured into the superconducting structures 121, 122). The JJ layer stack 130 may be a continuous, unstructured layer stack which is shown by the dash-dotted line in FIG. 1. The JJ layer stack 130 may extend across, e.g., cover, the entire substrate 110, for example.

The JJ layer stack 130 includes a JJ barrier layer (not shown). The JJ barrier layer is the functional layer of the JJ layer stack 130 which provides JJ tunneling.

For example, the JJ layer stack 130 may, e.g., comprise or be a three-layer stack of a superconducting/tunnel barrier/superconducting material. Possible three layers include, but are not limited to, Al/AIOx/Al, Nb/AlOx/Nb, or Ta/AlOx/Ta layer stacks. For example, other barrier layers than aluminum oxide AlOx may be used (such as, e.g., magnesium oxide MgOx, etc.), and also different combinations of superconducting materials may be used.

The JJ layer stack 130 may be deposited by sputtering or any other suitable deposition process. The JJ layer stack 130 may have a topography (e.g., is non-planar) due to previous structuring process(es) and optional additional structured layers arranged on the substrate 110 and/or the first structured superconducting layer 120, such as a structured dielectric base layer, for instance.

Still referring to FIG. 1, the JJ layer stack 130 is then structured to form a JJ structure 131. In particular, the parts of the JJ layer stack 130 overlaying (overlapping) the optional first structured dielectric base layer may be completely removed.

Structuring of the JJ layer stack 130 may include etching processes. For example, reactive ion etching (RIE) may be used for metal and dielectric etching of the JJ layer stack 130 to form the JJ structure 131. RIE is anisotropic and therefore suitable to form the JJ structure 131 with (approximately) vertical side walls. As shown in FIG. 1, the JJ structure 131 is electrically contacted at its bottom to a structure of the first structured superconducting layer 120, e.g., to the second superconducting structure 122.

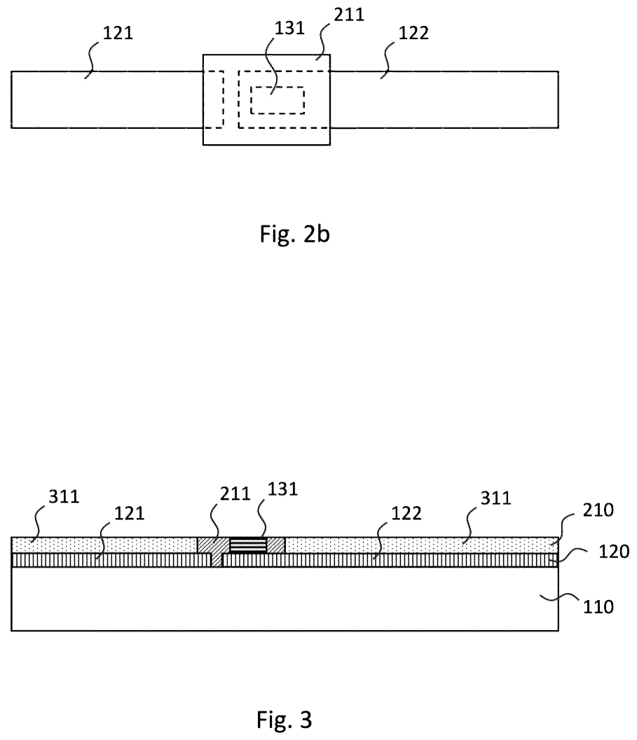

Referring to FIG. 2a, a first component 211 of a cover layer 210 is then formed in a first region, wherein the first region extends over and around the JJ structure 131. In other words, the first component 211 of the cover layer 210 fully surrounds previously uncovered surfaces of the JJ structure 131. The first component 211 of the cover layer 210 may be obtained by structuring an unstructured, continuous layer, which may, e.g., cover the entire substrate 110 as illustrated by the dash-dotted line in FIG. 2a. The first component 211 of the cover layer 210 may be formed from a sacrificial material to be removed at a later stage and may comprise or be of one of: a photoresist, carbon, silicon oxide, silicon nitride or a combination (oxynitride) of these materials. The material of the first component 211 of the cover layer 210 may be different from a material of the optional dielectric base layer (and thus can be selectively structured). The material of the first component 211 may fill gaps between structures 121, 122 of the first structured superconducting layer 120.

FIG. 2b illustrates a schematic top view of the intermediate product after forming the first component 211. As shown, the first component is of larger lateral extension than the JJ structure 131 such that the latter is fully enclosed by the first component 211 on a top surface facing away from the first structured superconducting layer 120 and on side surfaces of the JJ structure 131. The first component can further cover a portion of the first and/or second superconducting structures 121, 122 of the first structured superconducting layer 120 as illustrated in FIGS. 2a and 2b.

Referring to FIG. 3, a second component 311 of the cover layer 210 is then formed in a second region of the cover layer 210 different from the first region. For example, the second component 311 fully covers the region of the first structured superconducting layer 120 that not covered by the first component 211. In other words, the cover layer 210 comprising the first component 211 and the second component 311 fully covers the substrate 110. In yet other words, the second component 311 can be formed next to or surrounding the sacrificial material of the first component 211 in the same layer, e.g., the cover layer 210, and can be an inter-layer dielectric material. The second component 311 may be contiguous, e.g., laterally surrounding the first component 211, or be divided by the first component 211 within the cover layer 210. The material of the second component 311 may fill gaps between structures 121, 122 of the first structured superconducting layer 120.

The material of the second component 311 can be a dielectric such as silicon oxide, silicon nitride or a combination (oxynitride) of these materials. In particular, the materials of the first and second components 211, 311 are such that the first component 211 can be selectively etched against the material of the second component 311 (and other materials involved such as a materials of the JJ structure 131 or all materials forming the JJ structure 131 and the first structured superconducting layer 120). Thus, the first component 211 can be formed from a photoresist or carbon while the second component 311 can be formed from silicon nitride, for instance.

Still referring to FIG. 3, the cover layer 210 is thinned (e.g., is polished back by chemical mechanical polishing (CMP)) to the JJ structure 131. The thinning can be performed before or after depositing the material forming the second component 311. The result of the thinning step is a (substantially) flat top surface (the surface facing away from the substrate 110) of the cover layer 120 with the top surface of the JJ structure 131 being exposed at this stage of the manufacturing process. In other words, a thickness of the first component 211 and of the second component 311 can correspond to a thickness of the JJ structure 131 at least in the vicinity of the latter measured in a vertical direction perpendicular to a main plane of extension of the substrate 110.

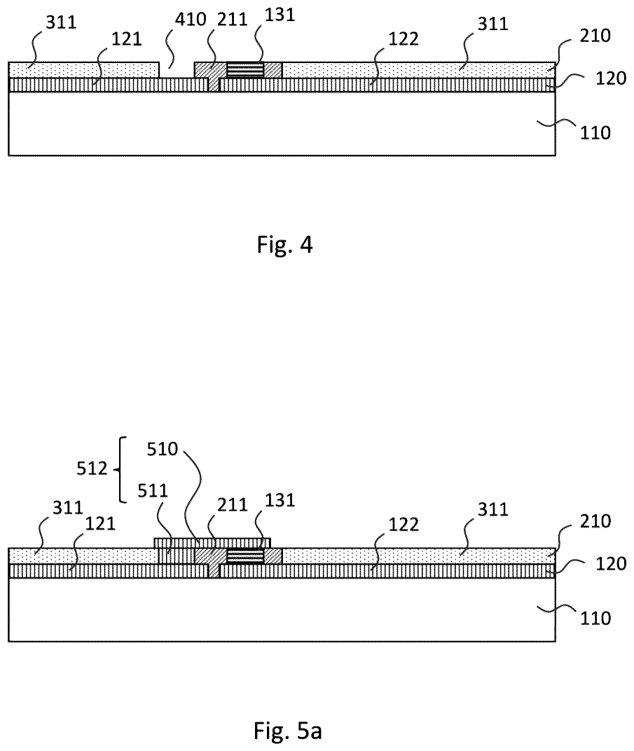

Referring to FIG. 4, an opening 410 in the cover layer 210 is formed in a selected location, e.g., within the second component 311 adjacent to the first component 211 as illustrated. The opening 410 exposes a portion of a structure of the first structured superconducting layer 120. In particular, the opening 410 exposes a portion of the first superconducting structure 121 that is not contacted to the bottom surface of the JJ structure 131. Forming the opening 410 the cover layer 210 on top of the JJ structure 212 may be carried out by a dedicated via etch process, e.g., by using RIE.

Further openings can be formed in the cover layer in further selected locations for exposing portions of the first superconducting layer 120, e.g., for forming contact pads.

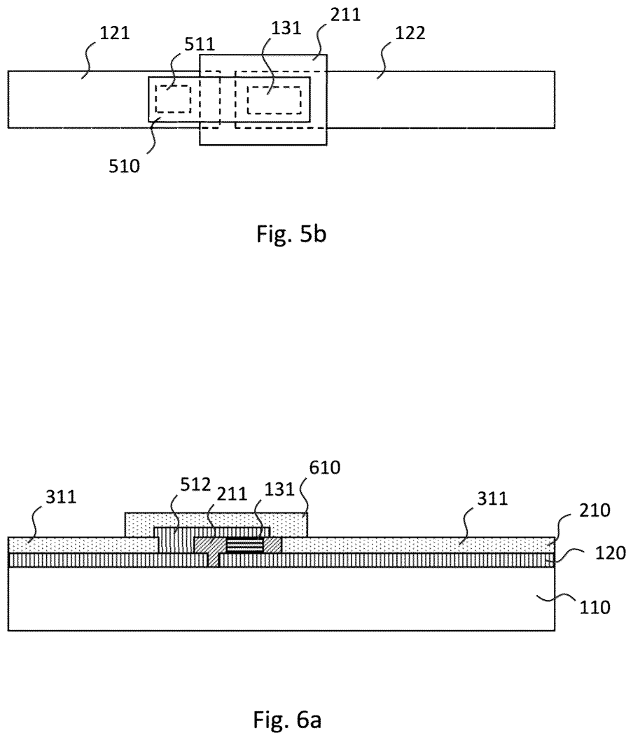

Referring to FIG. 5a, the opening 410 is filled with a superconducting material forming a via 511 that is contacted with the exposed portion of the first structured superconducting layer 120, in particular with the first superconducting structure 121. Like for the first superconducting material of the first structured superconducting layer 120, the superconducting material for filling the opening 410 and hence forming the via 511 can include Al, Nb or Ta. The superconducting material of the via 511 can be the same as the first superconducting material.

Still referring to FIG. 5a, a second structured superconducting layer 510 of a second superconducting material is formed over the substrate cover layer 210 overlaying (overlapping) at least the top surface of the JJ structure 131 and the via 511. The second structured superconducting layer 510, like the first structured superconducting layer 120, may be obtained by structuring an unstructured, continuous layer of the second superconducting material which may, e.g., be deposited on the entire cover layer 210. For example, the unstructured, continuous layer of the second superconducting material may be deposited by using a CVD (chemical vapor deposition) or PVD (physical vapor deposition) process, in particular by sputtering. Like for the first superconducting material of the first structured superconducting layer 120, the second superconducting material may, e.g., comprise or be of Al, Nb or Ta. The superconducting material of the second structured superconducting layer 510 can be the same as the first superconducting material or the superconducting material of the via 511.

The unstructured, continuous layer of the second superconducting material may then be structured to form the second structured superconducting layer 510. The second structured superconducting layer 510 forms an electrical interconnect between the JJ structure 131 and the via 511. In other words, the second structured superconducting layer 510 provides a third superconducting structure 512 connecting to the top surface of the JJ structure 131 and to the via 511, effectively forming a top contact of the JJ structure 131 that connects to the first superconducting structure 121, for instance.

Forming the via 511 and the second structured superconducting layer 510 (or deposition of the unstructured, continuous layer of the second superconducting material) may be performed in a single step, e.g., the second superconducting material can fill the opening 410 and be deposited on the cover layer 210 in a single deposition process. Thus, the via 511 and the second structured superconducting layer 510 after structuring can form a third superconducting structure 512 that interconnects the first superconducting structure 121 and the JJ structure 131, in particular the top surface of the JJ structure 131.

FIG. 5b illustrates a schematic top view of the intermediate product after forming the second structured superconducting layer 510. For illustrative purposes, the second component 311 of the cover layer 210 is excluded from this figure. As shown, the second structured superconducting layer 510 covers the top surface of the JJ structure 131 and the via 511. Thus, the first superconducting structure 121 is electrically contacted with the top surface of the JJ structure 131 through the via 511 and the second structured superconducting layer 510.

Forming the second structured superconducting layer 510 leaves a portion of the first component 211 of the cover layer 210 exposed. In other words, a portion of the top surface of the first component 211 of the cover layer 210 is not covered by, e.g., it is free from, the second structured superconducting layer 510. This facilitates the later removal of the sacrificial material of the first component 211 using an etch, for instance.

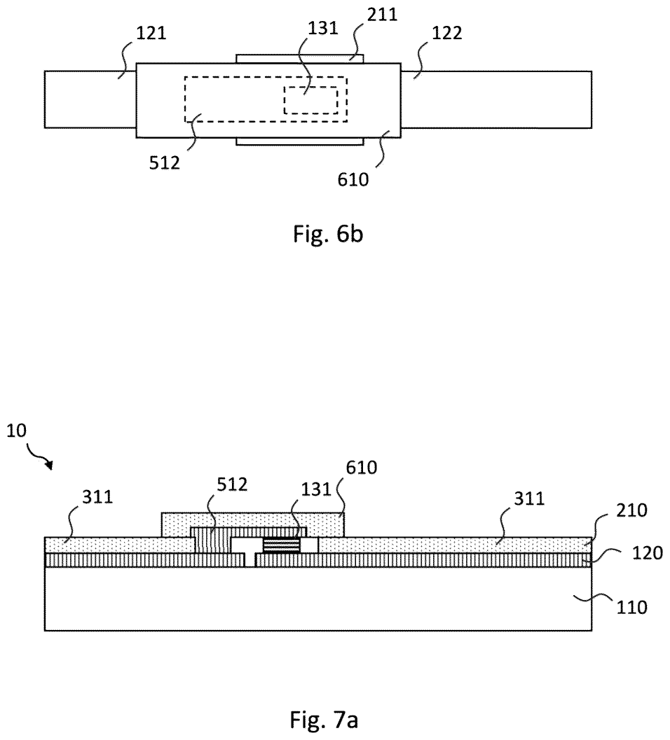

Referring to FIG. 6a, a structured encapsulation layer 610 is formed. The structured encapsulation layer 610 may, e.g., be formed from a continuous, unstructured layer which before structuring may cover the entire arrangement. The structured encapsulation layer 610 covers the second structured superconducting layer 510 and a portion of the first component 211 of the cover layer 210. The structured encapsulation layer 610 can further cover a portion of the second component 311 of the cover layer 210, e.g., in regions in which the second structured superconducting layer 510 does not cover the first component 211. The structured encapsulation layer 610 is formed from a second dielectric material, which may be any of the aforementioned dielectric materials, in particular of a low loss dielectric material such as, e.g., silicon nitride. For example, the second dielectric material is the same as the first dielectric material of the second component 311 of the cover layer 210.

In this example implementation, the second structured superconducting layer 510 and the via 511 form the third superconducting structure 512 as described above, e.g., as these elements are formed from the same superconducting material and/or during the same processing step.

FIG. 6b illustrates a schematic top view of the intermediate product after forming the structured encapsulation layer 610. For illustrative purposes, the second component 311 of the cover layer 210 is excluded from this figure. As shown, the structured encapsulation layer 610 covers the top surface of the third superconducting structure 512 (or the second structured superconducting layer 510). Thus, the third superconducting structure 512 is encapsulated by the structured encapsulation layer 610.

Forming the structured encapsulation layer 610 leaves a portion of the first component 211 of the cover layer 210 exposed. In other words, a portion of the top surface of the first component 211 of the cover layer 210 is not covered by, e.g., it is free from, the structured encapsulation layer 610. This facilitates the later removal of the sacrificial material of the first component 211 using an etch, for instance.

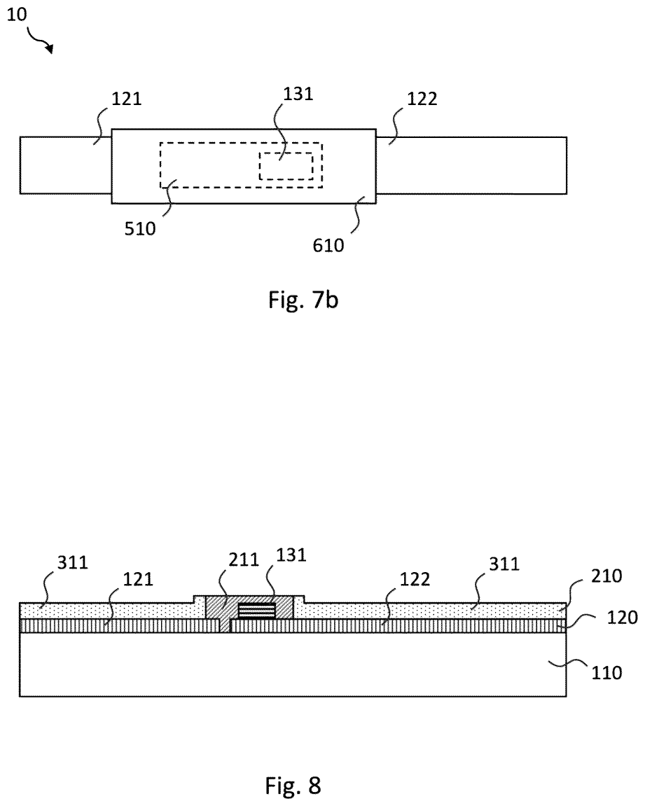

Referring to FIG. 7a, the first component 211 of the cover layer 210 formed from the sacrificial material is removed. In other words, the sacrificial material forming the first component 211 is removed. Removing the first component 211 can be achieved using a selective etch, for instance. Therein, an employed etchant has a significant higher etch rate regarding the sacrificial material than an etch rate of the first dielectric material, the second superconducting material, and the JJ structure 131—typically also referred to as a selectivity of the etch.

As a portion of the first component 211 is left exposed after forming the second structured superconducting layer 510 and the optional structured encapsulation layer 610, such exposed regions facilitate the etch process for removing the sacrificial material of the first component 211.

After removing the sacrificial material of the first component 211, a void is formed in place of the first component 211. This means that the JJ structure 131 is laterally surrounded by the void after removing the sacrificial material. In other words, the JJ structure 131—after the removal—is in vertical contact with the first structured superconducting layer 120, e.g., the second superconducting structure 122, at its bottom surface, and with the second structured superconducting layer 510, e.g., with the third superconducting structure 512, on its top surface, while side surfaces of the JJ structure 131 are in contact with the void and thereby exposed to air. In particular, the JJ structure is not in contact with any dielectric material, e.g., the first dielectric material of the second component 311 of the cover layer 210 and the second dielectric material of the structured encapsulation layer 610. Analogously, the JJ structure 131 is not in contact with any additional dielectric layers such as the optional base layer as described above.

FIG. 7b illustrates a schematic top view of the intermediate product after removing the first component 211 of the cover layer 210.

FIGS. 7a and 7b illustrate the superconducting integrated circuit device 10 according to this disclosure. It will be understood that this disclosure intends to illustrate the formation of a JJ structure with a dielectric-free surrounding. Further processing methods and steps can be applied to the device, e.g., further formation of openings and layers for forming further contact pads and/or circuit elements.

In the implementation exemplarily illustrated by FIGS. 1 to 7b, forming the cover layer 210 resulted in the latter being characterized by a planarized surface as illustrated in FIG. 3. This can be achieved using the aforementioned CMP step. In other implementations the cover layer 210 may be formed in alternative manners.

In this respect, referring to FIGS. 8 to 11 illustrating example stages of a second implementation of manufacturing a superconducting integrated circuit device, the JJ structure 131 is formed on a first structured superconducting layer 120 and encapsulated by the first component 211 of the cover layer 210 as described, e.g., in connection with FIGS. 1, 2a and 2b. Reference is made to the above description to avoid reiteration.

Referring to FIG. 8, a second component 311 of the cover layer 210 is then formed in a second region of the cover layer 210 different from the first region. For example, the second component 311 fully covers the region of the first structured superconducting layer 120 that not covered by the first component 211. In other words, the cover layer 210 comprising the first component 211 and the second component 311 fully covers the substrate 110. The second component 311 may be contiguous, e.g., laterally surrounding the first component 211, or be divided by the first component 211 within the cover layer 210. The material of the second component 311 may fill gaps between structures 121, 122 of the first structured superconducting layer 120.

The material of the second component 311 can be a dielectric such as silicon oxide, silicon nitride or a combination (oxynitride) of these materials. In particular, the materials of the first and second components 211, 311 are such that the first component 211 can be selectively etched against the material of the second component 311 (and other materials involved such as materials forming the JJ structure 131 and the first structured superconducting layer 120). Thus, the first component 211 can be formed from a photoresist or carbon while the second component 311 can be formed from silicon nitride, for instance.

Note that the cover layer 210 in this example implementation is not necessarily planarized before further processing and may therefore have topographic features on its top surface, e.g., in a transition region between the first component 211 and the second component 311 as illustrated. A height of the topographic features can be characterized by a thickness of the first component 211 and a thickness of the second component 311.

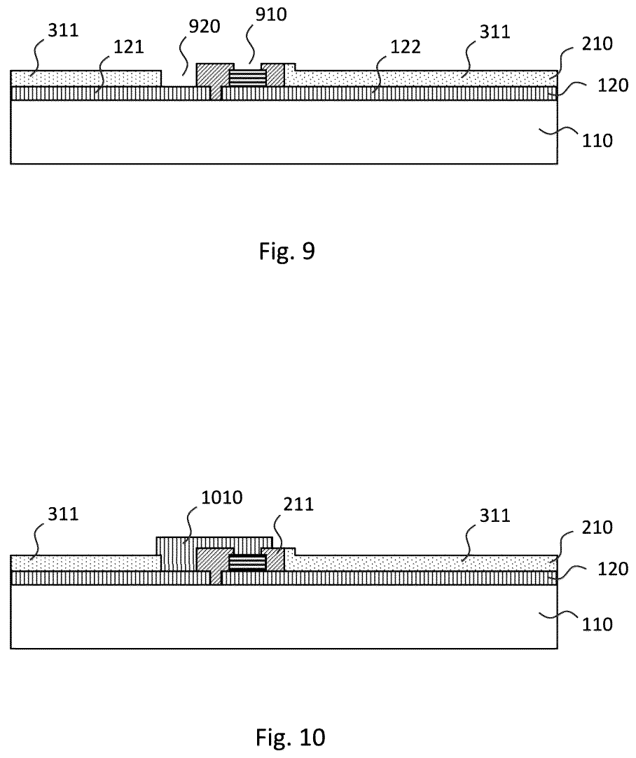

Referring to FIG. 9, a first opening 910 is formed in the cover layer 910 at a first selected location. The first opening 910 exposes at least a portion of the top surface of the JJ structure 131. A second opening 920 for exposing a portion of the first structured superconducting layer 120 is formed analogously to the opening 410 described with reference to FIG. 4 of the first implementation. The first and second openings 910, 920 can be formed in separate etching steps. Alternatively, the first and second openings 910, 920 can be formed concurrently in a single etching step, wherein an employed etchant is not selective regarding the sacrificial material of the first component 211 and the first dielectric material of the second component 311, and selective regarding the first superconducting material of the first structured superconducting layer 120. Yet alternatively, the first and second openings 910, 920 can both extend through the first component 211.

Referring to FIG. 10, a third superconducting structure 1010 is formed in an analogous manner to the third superconducting structure 512 as described with reference to FIG. 5a. Forming the third superconducting structure 1010 can comprise filling the second opening 920 with a superconducting material for forming a via and forming a second structured superconducting layer from a second superconducting material covering the top surface of the JJ structure and the via. The superconducting material of the via and the second superconducting material can be the same as described above. They can each or both be the same as the first superconducting material of the first structured superconducting layer 120. Forming the third superconducting structure 1010 leaves a portion of the first component 211 exposed.

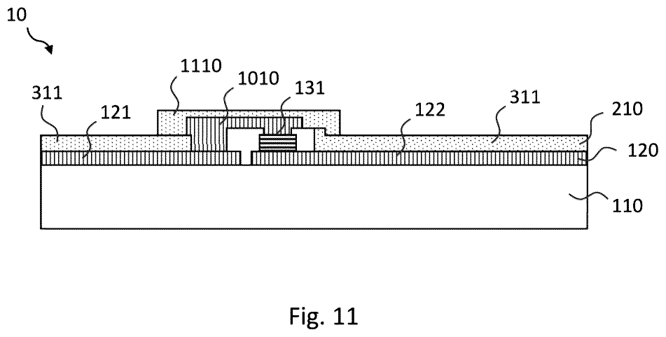

Referring to FIG. 11, a structured encapsulation layer 1110 is formed in an analogous manner to the structured encapsulation layer 610 as described with reference to FIG. 6a. The structured encapsulation layer 1110 covers, e.g., fully covers, the third superconducting structure 1010 and partially covers the first component 211 such that a portion of the first component 211 is exposed.

Subsequently, the sacrificial material of the first component 211 is removed in an analogous manner to the removal as described with reference to FIG. 7a.

The disclosure thus proposes different implementations of a technique to form tri-layer Josephson junctions without close-by dielectrics. The fringing fields surrounding this dielectric-free tri-layer Josephson junction during its operation will instead be located in the void surrounding the JJ structure, e.g., a vacuum, where lossy defect TLS are not prevalent. This significantly reduces the net dielectric loss budget of the tri-layer Josephson junction.

Although specific examples have been illustrated and described herein, it will be appreciated by those of ordinary skill in the art that a variety of alternate and/or equivalent implementations may be substituted for the specific examples shown and described without departing from the scope of the present implementation. This application is intended to cover any adaptations or variations of the specific examples discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

### ASPECTS

The following examples pertain to further aspects of the disclosure:
Aspect 1: A method of manufacturing a superconducting integrated circuit device comprises:
   providing a Josephson Junction, JJ, structure arranged on a first structured superconducting layer, wherein the first structured superconducting layer is formed from a first superconducting material arranged on a substrate;
   forming, over the first structured superconducting layer, a cover layer having a first component and a second component, wherein forming the cover layer comprises:
   forming the first component from a sacrificial material in a first region of the cover layer, the first component surrounding the JJ structure with at least a portion of a top surface of the JJ structure facing away from the substrate being uncovered by the sacrificial material; and
   forming the second component from a first dielectric material in a second region of the cover layer different from the first region;
   forming a via in the cover layer over a portion of the first structured superconducting layer;
   forming a second structured superconducting layer of a second superconducting material overlaying the top surface of the JJ structure and the via; and
   removing the first component.
Aspect 2: The method according to aspect 1, wherein forming the via comprises forming an opening in the cover layer in a selected location, thereby exposing the portion of the first structured superconducting layer, and filling the opening with a superconducting material, in particular the first or second superconducting material, interconnecting the structured first and second superconducting layers.
Aspect 3: The method according to aspect 1 or 2, wherein the first and second superconducting materials are the same material.
Aspect 4: The method according to one of aspects 1 to 3, further comprising, before (e.g., prior to) removing the first component, forming a structured encapsulation layer of a second dielectric material over the second structured superconducting layer and over a portion of the first component of the cover layer.
Aspect 5: The method according to aspect 4, wherein the first and second dielectric materials are the same material.
Aspect 6: The method according to one of aspects 1 to 5, wherein forming the cover layer comprises performing a chemical-mechanical polishing, CMP, step.
Aspect 7: The method according to one of aspects 1 to 6, wherein the sacrificial material is a material that has the capability of being selectively etched with respect to the first dielectric material and a material of the JJ structure.
Aspect 8: The method according to one of aspects 1 to 7, wherein the sacrificial material is one of: a photoresist, an oxide and carbon.
Aspect 9: The method according to one of aspects 1 to 8, wherein the first dielectric material is a nitride, in particular silicon nitride.
Aspect 10: The method according to one of aspects 1 to 9, wherein forming the second structured superconducting layer comprises leaving a portion of the first component of the cover layer exposed.
Aspect 11: The method according to one of aspects 1 to 10, wherein forming the cover layer comprises filling a void in the first structured superconducting layer with the sacrificial material or the first dielectric material.
Aspect 12: The method according to one of aspects 1 to 11, wherein forming the first component of the cover layer comprises laterally surrounding the JJ structure with the sacrificial material.
Aspect 13: The method according to one of aspects 1 to 12, wherein providing the JJ structure comprises:
   forming a first superconducting layer of the first superconducting material over the substrate;
   forming a JJ layer stack including a JJ barrier layer over the first superconducting layer;
   structuring the first superconducting layer to form the first structured superconducting layer; and
   structuring the JJ layer stack to form the JJ structure.
Aspect 14: The method according to aspect 13, wherein structuring the JJ layer stack is carried out alongside structuring the first superconducting layer.
Aspect 15: The method according to one of aspects 1 to 14, wherein the first structured superconducting layer comprises a first superconducting structure contacting the via, and a second superconducting structure connecting to a bottom surface of the JJ structure facing the substrate.
Aspect 16: The method according to one of aspects 1 to 15, wherein the via and the second structured superconducting layer form a third superconducting structure interconnecting the top surface of the JJ structure and the first structured superconducting layer.
Aspect 17: The method according to one of aspects 1 to 16, wherein the first structured superconducting layer provides a first superconducting structure, the second structured superconducting layer provides a second superconducting structure, and wherein the second superconducting structure connects to the JJ structure and to the first superconducting structure.
Aspect 18: The method according to one of aspects 1 to 17, wherein removing the sacrificial material provides a void laterally surrounding the JJ structure.
Aspect 19: The method according to one of aspects 1 to 18, wherein forming the cover layer comprises partially covering the top surface of the JJ structure with the sacrificial material.
Aspect 20: The method according to one of aspects 1 to 19, wherein the first superconducting material and the second superconducting material each comprise one of: Al, Nb and Ta.
Aspect 21: A superconducting integrated circuit device (10), comprising:
   a substrate;
   a first structured superconducting layer arranged on the substrate;
   a Josephson Junction, JJ, structure arranged on the first structured superconducting layer in a first region;
   a cover layer arranged on the first structured superconducting layer in a second region different from the first region; and
   an interconnect structure interconnecting a top surface of the JJ structure facing away from the substrate and a portion of the first structured superconducting layer;
   wherein the JJ structure is laterally surrounded by a void.

1. A method of manufacturing a superconducting integrated circuit device, the method comprising:
providing a Josephson Junction, (JJ) structure on a first structured superconducting layer, wherein the first structured superconducting layer is formed from a first superconducting material arranged on a substrate;
forming, over the first structured superconducting layer, a cover layer having a first component and a second component, wherein forming the cover layer comprises:
forming the first component from a sacrificial material in a first region of the cover layer, the first component surrounding the JJ structure with at least a portion of a top surface of the JJ structure, facing away from the substrate, being uncovered by the sacrificial material; and
forming the second component from a first dielectric material in a second region of the cover layer different from the first region;
forming a via in the cover layer over a portion of the first structured superconducting layer;
forming a second structured superconducting layer of a second superconducting material overlaying the top surface of the JJ structure and the via; and
removing the first component.

2. The method according to claim 1, wherein the first superconducting material and the second superconducting material are the same material.

3. The method according to claim 1, further comprising:
prior to removing the first component, forming a structured encapsulation layer of a second dielectric material over the second structured superconducting layer and over a portion of the first component of the cover layer.

4. The method according to claim 3, wherein the first superconducting material and the second superconducting material are the same material.

5. The method according to claim 1, wherein forming the cover layer comprises performing a chemical-mechanical polishing (CMP) step.

6. The method according to claim 1, wherein the sacrificial material is a material that is capable of being selectively etched with respect to the first dielectric material and a material of the JJ structure.

7. The method according to claim 1, wherein the sacrificial material is one of: a photoresist, an oxide, or carbon.

8. The method according to claim 1, wherein the first dielectric material is a nitride.

9. The method according to claim 1, wherein forming the second structured superconducting layer comprises leaving a portion of the first component of the cover layer exposed.

10. The method according to claim 1, wherein forming the cover layer comprises filling a void in the first structured superconducting layer with the sacrificial material or the first dielectric material.

11. The method according to claim 1, wherein forming the first component of the cover layer comprises laterally surrounding the JJ structure with the sacrificial material.

12. The method according to claim 1, wherein providing the JJ structure comprises:
forming a first superconducting layer of the first superconducting material over the substrate;
forming a JJ layer stack including a JJ barrier layer over the first superconducting layer;
structuring the first superconducting layer to form the first structured superconducting layer; and
structuring the JJ layer stack to form the JJ structure.

13. The method according to claim 12, wherein structuring the JJ layer stack is carried out alongside structuring the first superconducting layer.

14. The method according to claim 1, wherein the first structured superconducting layer comprises a first superconducting structure contacting the via, and a second superconducting structure connecting to a bottom surface of the JJ structure facing the substrate.

15. The method according to claim 1, wherein the via and the second structured superconducting layer form a third superconducting structure interconnecting the top surface of the JJ structure and the first structured superconducting layer.

16. The method according to claim 1, wherein the first structured superconducting layer provides a first superconducting structure,
wherein the second structured superconducting layer provides a second superconducting structure, and
wherein the second superconducting structure connects to the JJ structure and to the first structured superconducting layer.

17. The method according to claim 1, wherein removing the sacrificial material provides a void laterally surrounding the JJ structure.

18. The method according to claim 1, wherein forming the cover layer comprises partially covering the top surface of the JJ structure with the sacrificial material.

19. The method according to claim 1, wherein the first superconducting material and the second superconducting material each comprise one of: aluminum (Al), niobium (Nb), or tantalum (Ta) Al, Nb, or Ta.

20. A superconducting integrated circuit device, comprising:
a substrate;
a first structured superconducting layer arranged on the substrate;
a Josephson Junction (JJ) structure arranged on the first structured superconducting layer in a first region;
a cover layer arranged on the first structured superconducting layer in a second region different from the first region; and
an interconnect structure interconnecting a top surface of the JJ structure, facing away from the substrate, and a portion of the first structured superconducting layer;
wherein the JJ structure is laterally surrounded by a void.
